(19) United States
(12) Patent Application Publication
(10) Pub. No.: US 2017/0067154 A1
(43) Pub. Date: Mar. 9, 2017

(54) SYSTEMS AND METHOD FOR MICROPLASMA-BASED THREE-DIMENSIONAL PRINTING

(71) Applicant: BOARD OF TRUSTEES OF MICHIGAN STATE UNIVERSITY, East Lansing, MI (US)

(72) Inventor: Timothy A. Grotjohn, Okemos, MI (US)

(21) Appl. No.: 15/261,453

(22) Filed: Sep. 9, 2016

Related U.S. Application Data
(60) Provisional application No. 62/216,122, filed on Sep. 9, 2015.

(51) Int. Cl. C23C 16/44; B33Y 50/02; B33Y 10/00; B33Y 30/00; C23C 16/52; B29C 67/00

(52) U.S. Cl. CPC C23C 16/4418; C23C 16/52; B29C 67/0055; B29C 67/0085; B29C 67/0088; B33Y 10/00; B33Y 30/00; B33Y 50/02

(57) ABSTRACT

Systems and methods are described for using microplasmas in 3D printing to deposit materials, remove materials, or modify the properties of materials deposited on a given substrate surface. The resulting microplasma-based 3D printing enables the integration of different types of materials into the same 3D printed structure that is not possible with current technology.

### CROSS REFERENCE TO RELATED APPLICATIONS

This application claims the benefit of U.S. Provisional Application No. 62/216,122, entitled “Systems And Method For Microplasma-Based Three-Dimensional Printing,” filed on Sep. 9, 2015, the entirety of which is hereby expressly incorporated by reference.

### FIELD OF THE DISCLOSURE

The present disclosure relates generally to three-dimensional (3D) printing, and more particularly, to systems and methods for microplasma-based 3D printing.

### BACKGROUND

The background description provided herein is for the purpose of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

3D printing constitutes a raft of technologies, based on a number of different physical mechanisms, the common feature of which is the generation of a 3D physical object from a digital model. Generally speaking, the process is additive in nature, as materials are laid down only where needed, thus resulting in significantly less material wastage than traditional manufacturing techniques, which typically form parts by reducing or removing material from a bulk material.

3D printing technologies were initially established in the 1980s. The first wave of 3D printing technologies included stereolithography apparatuses, fused deposition modeling, and selective laser sintering. These technologies allowed manufacturers to create various 3D objects that improved upon manufacturing processes. As an example, injection molding manufacturers generally need to create a different mold for each desired part to be produced. However, if a specification for a part changed, the manufacturers would be required to create a new mold. Conversely, with the implementation of 3D printing, there is no need for a mold. Rather, a computer model replaces the mold, and the model can be updated or modified at any time as desired.

Currently, most 3D printers are capable of printing materials such as plastics, metals, or ceramics. To print a plastic object, a plastic thread is fed to a 3D printing head where the plastic is heated to a temperature sufficient to cause the plastic to flow. This flow of plastic is used to print a desired object such that when the plastic cools, the final shape of the plastic printed part takes shape. The printing of metals is generally done by using a metal powder that is spread evenly in a thin layer over a surface. A laser is then used to sinter the powder into a solid metal piece. This process is repeated to form the desired final shape of the part. Similarly, ceramics are printed by spreading a ceramic powder and then applying a resin to the ceramic in the regions that are to become the final structure. Afterward, any excess ceramic powder is removed and the part is sintered. Ceramics can also be formed by printing and sintering a clay material into the desired part shape.

Current 3D printers lack the ability to integrate different materials into the same printed part. Those that can print multiple materials on the same part require a full equipment change for each separate material. As a result, multiple manufacturing steps are required, which can be costly, inefficient, and time consuming.

### SUMMARY

The disclosed systems and methods utilize microplasmas in 3D printers to enable the integration of different types of materials, such as plastics, metals, ceramics, or glass, into the same part during the 3D printing process.

In an example, a computer-implemented method for printing 3D parts includes receiving, at one or more processors, a 3D model of a part and determining, at the one or more processors, a first portion of the 3D model of the part to be printed with a plastic or polymeric material. The method further develops, at the one or more processors, first instructions to be executed by a first print head to create the first portion of the 3D model of the part and determines, at the one or more processors, a second portion of the 3D model of the part to be printed with another material. The first and second portions are to be combined together to at least partially form the 3D model of the part. The method further includes developing, at the one or more processors, second instructions to be executed by a second print head to create the second portion of the 3D model of the part. The second print head operates via microplasma to print another material to create the second portion of the 3D model of the part. The developed first instructions and the developed second instructions are coordinated with one another to allow for the formation of the part using coordinated operation of the first print head and the second print head. The method further sends instructions to the first print head to print the plastic material to create the first portion of the 3D model of the part and sends instructions to the second print head to print the another material to create the second portion of the 3D model of the part.

In some approaches, a system for printing 3D parts includes a first print head, a second print head that operates with microplasma, and a control module including a memory having instructions for execution on one or more processors. The instructions, when executed by the one or more processors, cause the control module to receive a 3D model of a part, determine a first portion of the 3D model of the part to be printed with a first type of material, and determine a second portion of the 3D model of the part to be printed with a second type of material. The first and second portions are to be combined together to form at least a portion of the 3D model of the part. The instructions further activate the first print head to print the first type of material to create the first portion of the 3D model of the part and activate the second print head to print the second type of material to create the second portion of the 3D model of the part.

### BRIEF DESCRIPTION OF THE DRAWINGS

For a more complete understanding of the disclosure, reference should be made to the following detailed description and accompanying drawing figures, in which like reference numerals identify like elements in the figures, and in which:

FIG. 1 illustrates an example system for microplasma-based 3D printing in accordance with various aspects of the present invention;

FIG. 2 illustrates an example approach for microplasma-based 3D printing in accordance with various aspects of the present invention;

FIGS. 3a-3d illustrate perspective views of an example printing process in accordance with various aspects of the present invention; and

FIGS. 4a-4c illustrate perspective views of an alternative example printing process in accordance with various aspects of the present invention.

While the disclosed methods and apparatus are susceptible to embodiments in various forms, there are illustrated in the drawing (and will hereafter be described) specific embodiments of the invention, with the understanding that the disclosure is intended to be illustrative, and is not intended to limit the invention to the specific embodiments described and illustrated herein.

### DETAILED DESCRIPTION

Generally, the use of microplasmas in 3D printing approaches allow the addition of materials, removal of materials, and/or treatment of the surface of materials in small spatially localized regions. In particular, microwave energy is used to process gaseous feedstock containing a desired compound into a plasma stream. The plasma stream is then used to locally deposit or remove materials on a given substrate at an atom-by-atom level not possible with any traditional processing or additive manufacturing methods.

Techniques for creating and using microplasmas are described in detail in U.S. Pat. No. 6,759,808, U.S. Pat. No. 7,262,408, and U.S. Pat. No. 7,442,271, the entire disclosure of each of which are hereby expressly incorporated by reference.

An advantage of using microplasmas in 3D printing is their ability to be used to deposit materials that normally require high temperatures. Generally, the materials being deposited begin as gas phase precursors that are activated by the microplasma in order to adhere to a surface. These precursors would not be reactive and adhere to the surface at low temperatures (i.e., at room temperature or near room temperature). Without the use of microplasma, the precursors would require substantially high temperatures (e.g., several hundred degrees Celsius) to activate. By using microplasma, the precursors can be activated at substantially lower temperatures such that the deposition surface does not reach extreme temperatures that may damage the printed structure (this is especially the case for polymers and/or other plastic structures if the temperature is too high). Thus, the use of microplasma allows the deposition of materials at much lower temperatures than would be possible if the precursors were activated by a heated surface.

Another advantage of using microplasmas in 3D printing is that they allow the width of the materials being deposited to be easily adjusted by the plasma exiting from the print head. Typically, the size of the plasma stream can range from 10 micrometers to 1 millimeter. Further, the distance from the exit point of the print head and the structure being printed can be used to control the size of the plasma stream. Specifically, the further the plasma stream travels from the exit point of the print head to the surface, the more the plasma stream expands in width. Moreover, the thickness of the deposited layer can be adjusted from just a few atomic layers to thicker layers if the microplasma is left to deposit at the same region for a long time, or if the microplasma is passed over the same region many times.

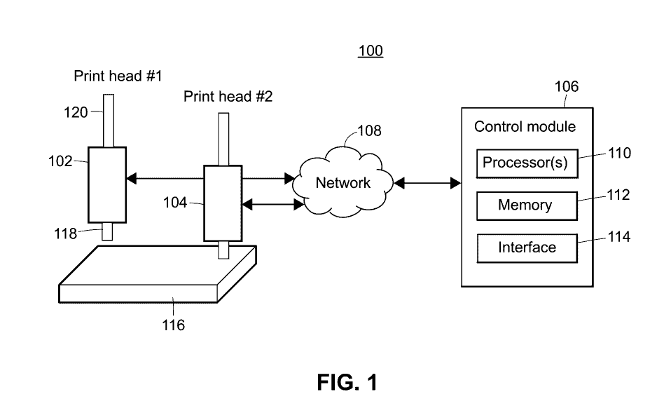

Turning to the drawings, FIG. 1 illustrates a block diagram of an example system 100 for microplasma-based 3D printing. The system 100 includes print heads 102 and 104, which may be part of a 3D printer system. The print heads 102 and 104 may be coupled to a control module 106 via a communication network 108 that can include wired and/or wireless links. The control module 106 may include one or more processors 110, a memory 112, and interfaces 114 (e.g., a display screen interface, a touchscreen interface, a keyboard interface, other input device interface, etc.). It is understood that while two print heads are shown in FIG. 1, in other embodiments and/or configurations, the system 100 may include any number of suitable print heads.

The print head 102 may be a microplasma-based print head. The microplasma-based print head 102 may create a stream or beam of plasma species that interacts with a surface of a substrate 116 to perform one or more of depositing a material on the surface of the substrate 116, removing a material from the surface of the substrate, or modifying the properties of a material deposited on the surface of the substrate 116.

The print head 102 may operate by creating a small plasma that flows out of a tube 118. The plasma may be formed from a feed 120 supplying a precursor gas or a mixture of precursor gases. The precursor gas or mixture of precursor gasses may be stored in a reservoir or other suitable container connected to the feed 120. Using a microwave or excitation tool, the precursor gas or mixture of precursor gases from the feed 120 may be excited into a plasma discharge by applying electrical energy (e.g., microwave energy) to the print head 102. Precursor gasses that contain metal species can be activated or decomposed in the plasma to create reactive species. For example, if an organometallic compound (e.g., trimethylaluminum) is used, the reactive species produced is aluminum. As a result, aluminum metal is present in the discharge from the tube 118. The aluminum metal then deposits on the surface 116 at the exit of the tube 118. A metal line or other desired shape is deposited on the substrate 116 upon moving the print head 102.

Similarly, precursor gasses that contain ceramic species (e.g., aluminum oxide) or glass species (e.g., silicon dioxide) can be activated in the plasma discharge resulting in traces of ceramic or glass being discharged from the tube 118. For glass species, the precursor gas may be tetraethyl orthosilicate (TEOS), for example. In this manner, different materials can be deposited by using different precursor gases.

Operationally, precursor gases can be employed in microplasma-based 3D printing using any number of approaches. In one embodiment, a single precursor gas is used to deposit one material from the print head 102. In another embodiment, a customized mixture or combination of materials can be deposited from the print head 102. For example, if a mixture of two organometallic compounds are used, such as, a first compound having aluminum and a second compound having copper, a metal can be deposited that is the compound mixture of aluminum and copper. Accordingly, by controlling the input precursor gas mixture percentages, a mixture of metals (percentage of each) in the final deposited metal layer can be controlled. In still other examples, material deposited from the print head 102 may be functionally graded. In this approach, a first or starting layer can be a first material, while the deposited layer can be either gradually or abruptly changed in composition. For example, a copper layer can be deposited on top of an aluminum layer either abruptly or gradually, where the respective aluminum and copper composition percentages gradually change from a purely aluminum bottom layer, through gradient mixed layers, to a final purely copper top layer. Of course, any number of material layer configurations may be achieved.

In some approaches, the deposition may begin with oxygen to improve the adhesion of a plastic surface. For example, an oxygen plasma may be used to create oxygen radicals that can interact with the surface of the plastic. This interaction can improve the adhesion of materials to plasma, including metals, other plastics, paints, and the like. Subsequently, a metal or other material layer is deposited onto the surface (e.g., the plastic surface previously treated with oxygen plasma). Either the same microplasma-based print head (e.g., the print head 102) or two (or more) different microplasma-based print heads can be used to deposit the metal layer.

The print head 102 can also be used to treat the surface of a part. In particular, a plasma flow can be applied to the part surface to make localized regions either hydrophobic or hydrophilic. For example, if the precursor gas is oxygen, then oxygen reactive species are generated that can change surface adhesion properties. Likewise, precursor gasses from the feed 120 can be used to create a plasma flow that removes or etches the surface of a part to form channels or holes, for example.

The print head 104 may be any type of print head used in 3D printing systems. In some examples, the print head 104 may be an additional microplasma-based print head that operates in a similar manner as the print head 102. In some examples, the print head 104 may be a standard print head used to print polymers and/or other plastic materials. In still other examples, the print head 104 may be a standard print head used to print metallic, polymer, wax, ceramic, glass, and/or biological materials. Other examples of materials and corresponding print heads are possible.

In some examples, the print head 102 and/or 104 may use the microplasma to modify a portion of the physical part as opposed to depositing a new layer. For example, the microplasma can be used to remove surface material and/or modify surface properties of an existing layer. An example is the oxygen plasma technique described herein. Affecting existing layers, through microplasma treatment, can be use separately or in conjunction with new layer formation.

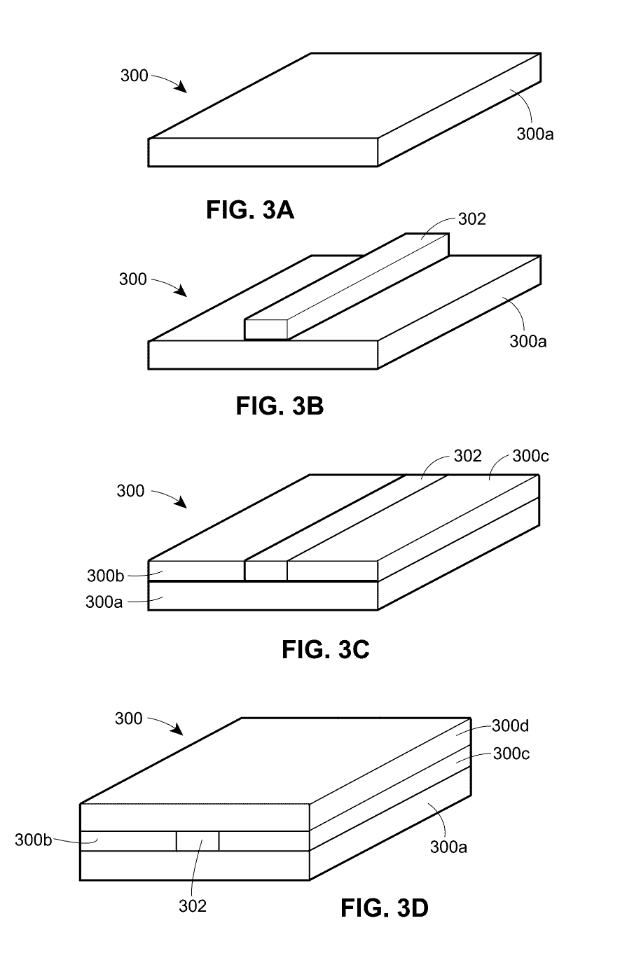

The print heads 102 and 104 may operate in conjunction to print a physical, multi-material part that integrates different types of materials into the same 3D printed structure. For example, as illustrated in FIG. 3a, the print head 104 of FIG. 1 may first print a lower portion 300a of a part 300. It is understood that the lower portion 300a (as well as the remainder of the part 300) may be any size, shape, gradient, and/or configuration, and can alternatively be printed from a metallic substrate such as aluminum or a combination of substrates. As illustrated in FIG. 3b, the print head 102 of FIG. 1 may then print a metal layer or layers (e.g., in the form of metal lines 302, shapes, or any other pattern) on an upper surface of the lower portion 300a. It is understood that the metal lines 302 may be any size, shape, gradient, and/or configuration.

As illustrated in FIGS. 3c and 3d, the print head 104 may then print additional remaining segments 300b, 300c, 300d of the plastic part 300 around the printed metal structure 302. In FIG. 3c, the print head 104 prints any number of intermediate layers 300b, 300c that surround the printed metal structure 302 and are flush with the height of the printed metal structure 302. As illustrated in FIG. 3d, the print head 104 prints an upper portion 300d that covers the printed metal structure 302. In this way, the printed metal structure 302 (e.g., an antenna for transmitting and/or receiving electronic signals) may be formed inside a plastic sheathing or other housing 300. In other words, the printed metal structure 302 may be “embedded” in the housing as one of the manufacturing steps of the housing 300. Accordingly, there is no need to first form a plastic shell having a designated area for placement of the metal layer, then place the metal layer in this designated area, and subsequently enclose the metal layer in the remainder of the shell.

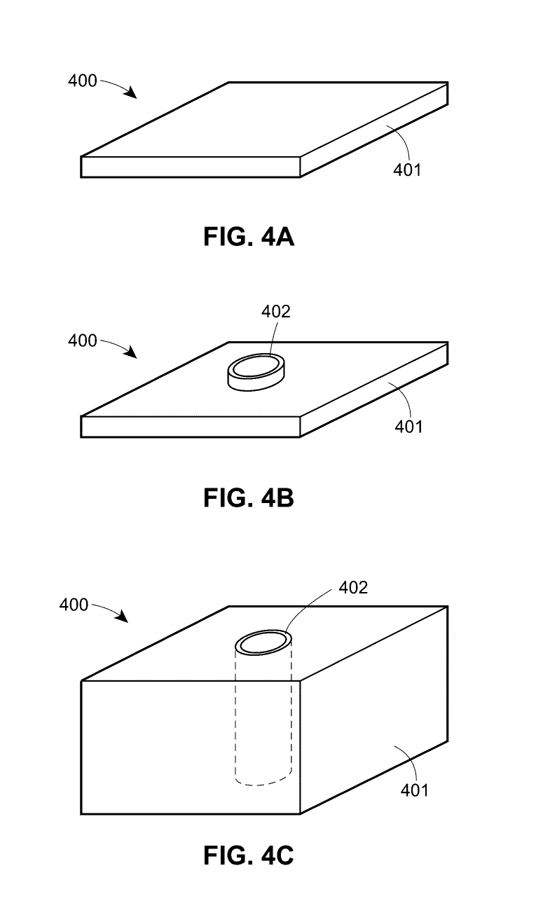

As another similar example and as illustrated in FIGS. 4a-4c, the print heads may print a part 400 formed from a second material (in this example, a tube forming a channel therethrough) in an axial configuration. As illustrated in FIG. 4a, the print head 104 of FIG. 1 may first print a base 401 of a plastic part 400 up to a desired “height” or thickness. As illustrated in FIG. 4b, the print head 102 of FIG. 1 may subsequently print a glass or ceramic structure 402 on top of the base of the plastic part 400 that begins to form a channel having a height. As illustrated in FIG. 4c, the print heads 102, 104 may then alternate by printing layers of each respective material in designated locations, thereby gradually building an outer part constructed from a first material that surrounds the glass or ceramic structure 402. The resulting structure 402 may be a glass (or ceramic)-lined channel inside the part 400 for fluid flow. In other examples, the structure 402 may be first printed to a certain length (thereby extending from the base), and the base 401 may be subsequently printed to become flush with the structure. This process can repeat until the part 400 reaches a desired dimension.

It is understood that in some examples, the structure 402 is not hollow and does not form a tube or channel. Rather the structure 402 may have a solid, wire-like configuration, and can be constructed from a metallic material. Further, it is understood that in some examples, the tube-shaped structure 402 may be formed according to the procedure described relative to FIGS. 3a-3d, whereby the print heads 102, 104 operate in a “horizontal” manner in which axial lengths of the structure 402 are formed in subsequent layers.

Generally speaking, the system 100 may use two or more print heads, with each print head having a different function (e.g., printing a different material). In some examples, the print heads may be configured to operate individually, and in other examples, multiple print heads may be operated at the same time. Each print head may operate using independent motion control (e.g., in the x, y, and z directions). Alternatively or additionally, some or all of the print heads may be fixed in position, and a surface or table holding the part being printed may be moved. Accordingly, by using the two or more print heads or by changing the mixture of precursor gases that are fed to the print heads versus time and position, it is possible to obtain controlled variations in the spatial composition on a microscopic and macroscopic scale in the deposited material. That is, the control module 106 can control precursor gas mixtures at the scan head 102 or upstream at a computer controlled precursor gas storage system. Such controlled variations allow functional materials to be formed in order to achieve multiple criteria in the same 3D part, such as corrosion resistance, hardness, hydrophobicity, and the like.

Potential applications for using microplasma-based 3D printing may include printing metal conductive lines for printed electronics, printing metal conducting lines on or inside 3D parts or shapes, printing metal lines inside 3D parts as they are formed (e.g., buried antennas for wireless communication), localized printing of different surface properties (e.g., hydrophobilic properties, hydrophilic properties, adhesive properties, wear properties, friction properties, visual appearance properties, corrosion resistance properties, etc.), performing local area surface modifications, etching or deposition on various microscale structures without the need for photolithography masking, forming complex 3D structures with a mix of metals, plastics, glass, and ceramics, etc.

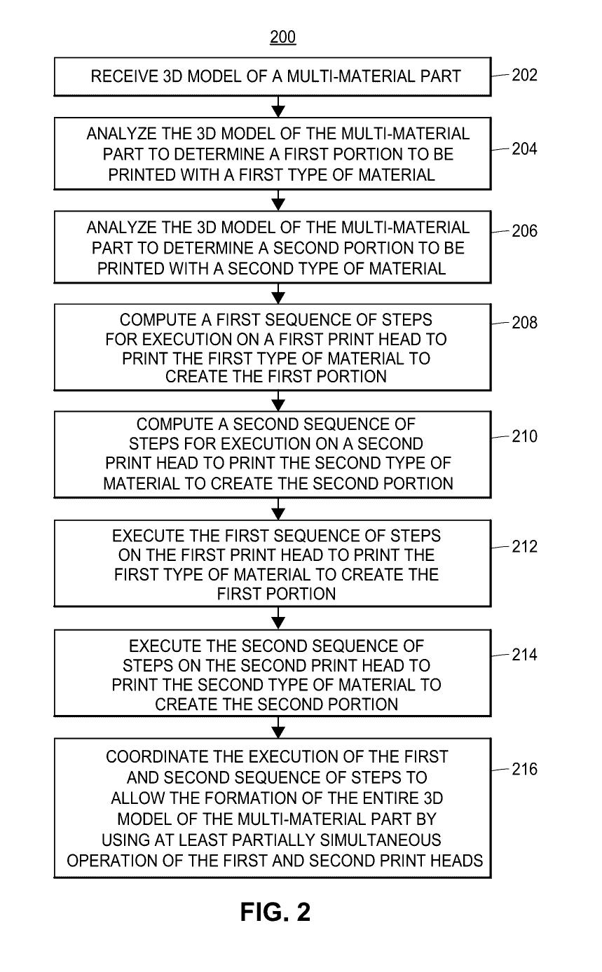

FIG. 2 illustrates a flow diagram of an example method 200 for microplasma-based 3D printing. The method 200 may include one or more blocks, routines or functions in the form of computer executable instructions that are stored in a tangible computer-readable medium (e.g., 112 of FIG. 1) and executed using one or more processors (e.g., 110 of FIG. 1), for example through one or more subroutines stored in the memory 112 each corresponding to one or more aspects of the method 200.

The method 200 may begin by receiving a 3D model data file representing a multi-material part (block 202). The multi-material part may be any physical part or object made from a combination of plastic, metal, ceramic, glass, crystal, and/or other materials.

Next, the method 200 analyzes the 3D model of the multi-material part to determine a first portion to be printed with a first type of material (block 204), for example, a casing made from a plastic material. Generally, the 3D model is of a part that may have numerous sections, surfaces, regions, and/or areas intended to be constructed from the different materials. For example, the multi-material part may be a glass-lined channel used in fluid flow experiments. The glass-lined channel may be surrounded by or embedded in a plastic casing.

The 3D model data file corresponding to the 3D (e.g., metadata appended to the 3D model) may be arranged in a number of configurations, such as, for example a matrix or matrices having a number of data structures or fields that detailing various aspects of the 3D model. The method 200 analyzes the 3D model by identifying the data structure corresponding to a material type, and then processes corresponding information to identify the location of areas constructed from different materials. In some approaches, material information may be explicitly illustrated using a characteristic of the model. For example, the 3D model may use a certain color, texture, and/or surface to distinguish between materials. As a result, at block 204, the method 200 may scan or process the metadata directly and/or characteristics of the 3D model to determine portions which will be printed different materials. Accordingly, the corresponding 3D model data file of the part will reflect the presence of multiple materials, thus the method 200 will distinguish between each material during the analysis step.

The method 200 then analyzes the 3D model of the multi-material part to determine a second portion to be printed with a second type of material (block 206). Continuing with the above example, the second portion of the multi-material part may be the glass-lined channel. Thus, the method 200 may determine the second portion is to be printed with the glass material by scanning or processing the data structures directly and/or characteristics of the 3D model.

In some examples, the method 200 can analyze the 3D model of the multi-material part to determine whether to affect or modify an existing layer of the first and/or the second portion. Similarly, the method 200 can analyze the 3D model to determine whether an existing layer should be modified or whether a new layer should be deposited. For example, the method 200 may be designed to identify, from the 3D model data, the material for an existing layer and the material for a subsequent layer to be formed thereon. Based on these two materials, the method 200 may determine that for some material combinations, the system should first affect the existing layer, e.g., through a microplasma treatment, before forming the second layer. The method 200 may access a materials database or table, or other data structure that identifies conditions under which an existing layer is selectively affected or deposited upon. In some examples, the method 200 may be designed to always affect layers of certain type, e.g., certain materials, certain shapes, certain positions, within an entire 3D model.

Subsequently, the method 200 computes a first sequence of steps for execution on a first print head to print the first type of material to create the first portion (block 208). The first sequence of steps may be a set of instructions that directs the movement of the first print head in the x, y, and z directions in order to create the structure or shape of the first portion of the multi-material part.

The method 200 also computes a second sequence of steps for execution on a second print head to print the second type of material to create the second portion (block 210). Similar to the first sequence of steps, the second sequence of steps may be a set of instructions that directs the movement of the second print head in the x, y, and z directions in order to generate the structure of the second portion of the multi-material part.

The method 200 then proceeds to execute the first sequence of steps on the first print head to print the first type of material to create the first portion (block 212). Further, the method 200 proceeds to execute the second sequence of steps on the second print head to print the second type of material to create the second portion (block 214).

The method 200 also coordinates the execution of first and second sequence of steps to allow the formation of the 3D model of the multi-material part by using at least partially simultaneous operation of the first and second print heads. Here, the method 200 may operate the first and second print heads in tandem to create the overall structure of the multi-material part. For example, the method 200 may correlate the movements of the first and second print heads such that the first portion is printed at the same time as the second portion. This allows the multi-material part to be printed faster and more efficiently. In an example, the method 200 may operate the first print head and the second print head iteratively to create at least a portion of the 3D model of the multi-material part. The coordination achieved by the method 200 may include coordination that varies based on the 3D model, coordination that varies based on the materials being used to form the model, and/or coordination that varies based on the type of print heads. For example, a control module may adjust the print speed of the microplasma and metal deposition depending on whether the previous layer is metal or plastic, the metal of the deposition layer to be applied, or metal composition mix of that deposition layer.

In some examples, the control module may first use a data string of the 3D model corresponding to a first layer or number of layers of the part to be printed and determine the desired material. The control module may next compare the desired material to the material in one or both of the print heads to determine which print head to be used to print the desired number of layers. Upon detecting a change in materials in a subsequent data string of the 3D model, the control module may again compare the desired material to the material in one or both of the print heads to determine which print head to be used. Based on a number of factors (such as, for example, desired layer thickness, width of the feature being printed, and/or heat sensitivity, or maximum allowed temperature of the material being printed), the control module determines a process for using each of the print heads to form a part. These factors can also determine if print parameters (e.g., print speeds, the order in which materials or elements are deposited, etc.) should be adjusted.

In some examples, the sequence of steps, the number of steps, the amount of deposition per step, and/or other characteristics of the print heads of block 212 or 214 may be affected by the operation of the other print head. For example, the data determined for execution by block 214 may result in a change in the operation of the block 212, and vice versa. Such interdependent control, when used, may further optimize deposition of the two material types depending on the desired 3D model. Moreover, such interdependence may be extended to examples of the present techniques having more than two print heads and the ability to print more than two different material types.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Additionally, certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired), or temporarily configured (e.g., programmed) to operate in a certain manner or to perform certain operations described herein. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules can provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses) that connects the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and can operate on a resource (e.g., a collection of information).

The various operations of the example methods described herein may be performed, at least partially, by one or more processors that are temporarily configured (e.g., by software) or that are permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or by processor-implemented hardware modules. The performance of certain of the operations may be distributed among the one or more processors, not only residing within a single machine (having different processing abilities), but also deployed across a number of machines. In some example embodiments, the processors may be located in a single location (e.g., deployed in the field, in an office environment, or as part of a server farm); while in other embodiments the processors may be distributed across a number of locations.

Unless specifically stated otherwise, discussions herein using words such as “processing,” “computing,” “calculating,” “determining,” “presenting,” “displaying,” or the like may refer to actions or processes on a GPU thread that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the description. This description, and the claims that follow, should be read to include one or at least one and the singular also includes the plural unless it is obvious that it is meant otherwise.

While the present invention has been described with reference to specific examples, which are intended to be illustrative only and not to be limiting of the invention, it will be apparent to those of ordinary skill in the art that changes, additions and/or deletions may be made to the disclosed embodiments without departing from the spirit and scope of the invention.

The foregoing description is given for clearness of understanding; and no unnecessary limitations should be understood therefrom, as modifications within the scope of the invention may be apparent ⁻hose having ordinary skill in the art.

What is claimed:

1. A computer-implemented method for printing three-dimensional (3D) parts, the computer implemented method comprising:
receiving, at one or more processors, a 3D model representative of a physical part;
determining, at the one or more processors, a first portion of the 3D model of the physical part to be printed with a first material;
developing, at the one or more processors, first instructions to be executed by a first print head to create the first portion of the physical part;
determining, at the one or more processors, a second portion of the 3D model of the physical part to be printed with a second material, wherein the first and second portions are adapted to be combined to form at least a portion of the physical part;
developing, at the one or more processors, second instructions to be executed by a second print head to create the second portion of the physical part, wherein the second print head operates using microplasma to print the second material to create the second portion of the physical part;
wherein the developed first instructions and the developed second instructions are coordinated to allow for the formation of the physical part using coordinated operation of the first print head and the second print head;
sending instructions to the first print head to print the first material to create the first portion of the physical part; and
sending instructions to the second print head to print the another material to create the second portion of the physical part.

2. The computer-implemented method of claim 1, further comprising operating the second print head to print the second material by:
inputting a precursor gas that contains the second material;
applying electrical energy to the print head to create a plasma discharge; and
flowing the precursor gas in the plasma discharge to create a stream of plasma species that interact with a surface to perform one or more of depositing the second material on the surface, removing the second material from the surface, or modifying the properties of the second material deposited on the surface.

3. The computer-implemented method of claim 1, wherein the steps of determining the first portion of the 3D model of the physical part to be printed with the first material and determining the second portion of the 3D model of the physical part to be printed with the second material comprise analyzing at least one characteristic of the 3D model.

4. The computer-implemented method of claim 3, wherein the at least one characteristic comprises at least one of: a) metadata containing material information of at least the first portion and the second portion; b) a color representative of a desired material; c) a texture representative of a desired material; and d) a surface representative of a desired material.

5. The computer-implemented method of claim 1, wherein the first material is a polymer.

6. The computer-implemented method of claim 1, wherein the second material includes at least one of a metal, a ceramic or a glass.

7. The computer-implemented method of claim 1, wherein the first print head and the second print head operate iteratively to create the physical part.

8. A system for printing three-dimensional (3D) parts, the system comprising:
a first print head;
a second print head adapted to operate with microplasma; and
a control module including a memory having instructions for execution on one or more processors, wherein the instructions, when executed by the one or more processors, cause the control module to:
receive a 3D model representative of a physical part;
determine a first portion of the 3D model to be printed with a first type of material;
determine a second portion of the 3D model to be printed with a second type of material, wherein the first and second portions are adapted to be combined to form at least a portion of the physical part;
activate the first print head to print the first type of material to create the first portion of the physical part; and
activate the second print head to print the second type of material to create the second portion of the physical part.

9. The system of claim 8, wherein in response to the control module determining the second portion of the 3D model to be printed with the second type of material, the second print head is adapted to print the second type of material by:
receiving a precursor gas, the precursor gas containing the second type of material;
applying electrical energy to the print head to create a plasma discharge; and
releasing the precursor gas to form a flow in the plasma discharge to create a stream of plasma species that interact with a surface to perform one or more of depositing the second material on the surface, removing the second material from the surface, or modifying the properties of the second material deposited on the surface.

10. The system of claim 8, wherein the memory has further instructions that, upon being executed by the one or more processors, cause the control module to determine the first portion of the 3D model to be printed with a first type of material and the second portion of the 3D model to be printed with a second type of material by analyzing at least one characteristic of the 3D model.

11. The system of claim 10, wherein the at least one characteristic comprises at least one of: a) metadata containing material information of at least the first portion and the second portion; b) a color representative of a desired material; c) a texture representative of a desired material; and d) a surface representative of a desired material.

12. The system of claim 8, wherein the first type of material is a polymer.

13. The system of claim 8, wherein the second type of material includes at least one of a metal, a ceramic or a glass.

14. A system for printing three-dimensional (3D) parts, the system comprising:
a first print head;
a second print head adapted to operate with microplasma; and
a control module including a memory having instructions for execution on one or more processors, wherein the instructions, when executed by the one or more processors, cause the control module to:
receive a 3D model representative of a physical part;
determine a first portion of the 3D model to be printed with a first type of material;
determine a second portion of the 3D model to be modified, wherein the first and second portions are adapted to be combined to form at least a portion of the physical part;
activate the first print head to print the first type of material to create the first portion of the physical part; and
activate the second print head to modify the second portion of the physical part.

15. The system of claim 14, wherein in response to the control module determining the second portion of the 3D model to be modified, the second print head is adapted to modify the second portion of the physical part by:
receiving a precursor gas, the precursor gas containing the second type of material;
applying electrical energy to the print head to create a plasma discharge; and
releasing the precursor gas to form a flow in the plasma discharge to create a stream of plasma species that interact with a surface to perform one or more of removing the material from the surface, or modifying the properties of the surface.

16. The system of claim 14, wherein the memory has further instructions that, upon being executed by the one or more processors, cause the control module to determine the first portion of the 3D model to be printed with a first type of material and the second portion of the 3D model to be modified by analyzing at least one characteristic of the 3D model.

17. The system of claim 16, wherein the at least one characteristic comprises at least one of: a) metadata containing material information of at least the first portion and the second portion; b) a color representative of a desired material; c) a texture representative of a desired material; and d) a surface representative of a desired material.

18. The system of claim 14, wherein the first type of material is a polymer.

19. The system of claim 14, wherein the memory further has instructions to cause the control module to determine whether to affect an existing layer of at least one of the first portion and the second portion.

20. The system of claim 14, wherein the memory further has instructions to cause the control module to determine whether to affect an existing layer or to deposit a new layer of at least one of the first portion and the second portion.
